(19) United States
(12) Patent Application Publication
(10) Pub. No.: US 2022/0391566 A1
(43) Pub. Date: Dec. 8, 2022

(54) MACHINE LEARNING MODELS FOR PREDICTING DETAILED ROUTING TOPOLOGY AND TRACK USAGE FOR ACCURATE RESISTANCE AND CAPACITANCE ESTIMATION FOR ELECTRONIC CIRCUIT DESIGNS

(71) Applicant: Synopsys, Inc., Mountain View, CA (US)

(72) Inventors: Yi Li, San Jose, CA (US); Prasanna Venkat Srinivas, Cupertino, CA (US)

(21) Appl. No.: 17/831,380

(22) Filed: Jun. 2, 2022

Related U.S. Application Data
(60) Provisional application No. 63/197,761, filed on Jun. 7, 2021.

(51) Int. Cl. G06F 30/27; G06F 30/394; G06F 30/392

(52) U.S. Cl. CPC G06F 30/27; G06F 30/394; G06F 30/392

(57) ABSTRACT

A system receives a netlist representation of a circuit design. The system performs global routing using the netlist representation to generate a set of segments. A segment represents a portion of a net routed by the global routing. The system provides features extracted from a segment as input to one or more machine learning models. Each of the one or more machine learning models is configured to predict attributes of the input segment. The predicted attributes have more than a threshold correlation with corresponding attributes determined using detailed routing information. The system executes the one or more machine learning models to predict attributes each of a set of segments output by global routing of the netlist. The system determines parasitic resistance and parasitic capacitance values for nets of the circuit design based on the predicted attributes.

### CROSS REFERENCE TO RELATED APPLICATIONS

This application claims a benefit of U.S. Patent Application Ser. No. 63/197,761, filed Jun. 7, 2021, the contents of which are incorporated by reference herein in its entirety.

### TECHNICAL FIELD

The present disclosure relates to physical routing of electronic circuits in general and more specifically to machine learning models for predicting detailed routing topology and track usage for accurate estimation of resistance and capacitance for electronic circuits.

### BACKGROUND

Routing is an important process in the physical design of electronic circuits. After floor planning and placement, routing is performed to determine the path for interconnecting pins of a netlist representing a circuit design. Due to complexity of circuits, the routing process uses a two stage approach that performs global routing (GR) followed by detailed routing (DR). Global routing generates an approximate route for nets. Detailed routing determines the exact tracks and vias for nets. If there is poor correlation between global route and detailed route, estimates of parameters of the circuit design determined based on the global route are likely to be inaccurate. For example, estimates of parasitic resistance and capacitance based on nets of the circuit design are likely to be inaccurate. Inaccurate estimates of resistance and capacitance of nets cause results of subsequent stages of the design process to be inaccurate as well.

### SUMMARY

A system receives a netlist representation of a circuit design. The system performs global routing using the netlist representation to generate a set of segments. A segment represents a portion of a net routed by the global routing. The system provides features extracted from a segment as input to one or more machine learning models. Each of the one or more machine learning models is configured to predict attributes of the input segment. The predicted attributes have more than a threshold correlation with corresponding attributes determined using detailed routing information. The system executes the one or more machine learning models to predict attributes each of a set of segments output by global routing of the netlist. The system determines parasitic resistance and parasitic capacitance values for nets of the circuit design based on the predicted attributes.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 shows example routing layer illustrating unit R and C of one pitch and two pitch, according to an embodiment.

FIG. 2 shows example layer unit resistance for different layers of an electronic circuit, according to an embodiment.

FIG. 3 shows a system architecture of a computing system for machine learning based predicting of detailed routing topology according to an embodiment.

FIG. 4 illustrates an example process for performing place and route of an electronic circuit design according to an embodiment.

FIG. 5 is a flowchart illustrating a process for training machine learning models for predicting detailed routing information based on global routing data, according to an embodiment.

FIG. 6 illustrates process for generating training data based on variation between global routing and detailed routing according to an embodiment.

FIG. 7 depicts a flowchart of various processes used during the design and manufacture of an integrated circuit in accordance with some embodiments of the present disclosure.

FIG. 8 depicts an abstract diagram of an example computer system in which embodiments of the present disclosure may operate.

The figures depict various embodiments of the present disclosure for purposes of illustration only. One skilled in the art will readily recognize from the following discussion that alternative embodiments of the structures and methods illustrated herein may be employed without departing from the principles of the disclosure described herein.

### DETAILED DESCRIPTION

The electronic design automation of a circuit design includes various stages including placement, routing, clock optimization, and so on. Routing of a circuit design includes global routing and detailed routing. Global routing performs coarse-grain assignment of routes to route regions. In global routing, the circuit design is partitioned into a grid of rectangles referred to as global cells or tiles. Global routing typically ignores details such as the exact geometry of each wire or pin. Global routing may assign a list of routing regions to each net without specifying the actual geometric layout of wires. Global routing implements net connections that are not assigned to the tracks.

A net of a netlist includes one or more wire segments (also referred to as segments or net segments). A via is an electrical connection (contact) between wire segments on adjacent layers. The distance between two tracks of nets is referred to as a pitch.

Embodiments here use machine learning models for predicting detailed routing information including topology and layer track usage for a physical design of an electronic circuit generated by global routing. The track usage information is used by a global routing RC (resistance and capacitance) extractor to generate accurate parasitic data including parasitic resistance and capacitance. Good correlation between global routing design (GR) and detail routing design (DR) improves quality of results and runtime of circuit design.

Using the machine learning models to predict the detail routing topology variations and layer track usage for the nets in global design improves the parasitic resistance and capacitance (also referred to as the parasitics) correlation in a global routing based design optimization flow. More precise determination of parasitic resistance and capacitance in global routing based design optimization flow results in determination of more precise timing data and results in more accurate optimization in placement and routing and subsequent circuit design processes to achieve better quality results, such as timing, area, and power.

Advantages of the present disclosure include, but are not limited to, improving the accuracy of the circuit design analysis performed and improving the efficiency of the entire design process. The improvement in accuracy of the analysis results since more accurate parasitics are determined at an early stage. Due to the accurate analysis, fewer iterations of the design process are needed in the overall analysis cycle, thereby improving the efficiency of the entire design process. This further results in improved utilization of computational resources used for the design process.

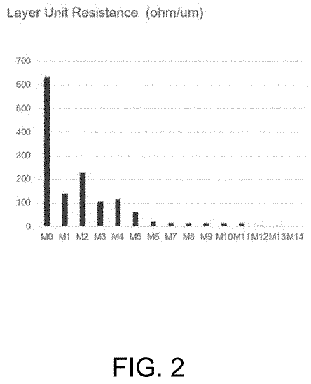

Various factors cause discrepancy and variation between global routing design and detail routing design. In detail routing design, even though net segments may be routed on the same layer on similar congested area, the track distance from the shapes of these nets to the neighbor shape could be quite different compared to the result of global routing. FIG. 2 illustrates large spacing variation when segments are routed on the track in detail routing.

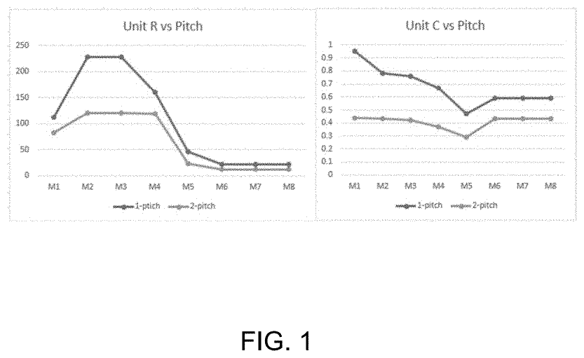

FIG. 1 shows example routing layer illustrating unit R (resistance) and C (capacitance) of one pitch and two pitch. The spacing distance to the neighbor shapes is one of the main factors relevant for extracting parasitic resistance/capacitance for a net in the VLSI circuit. In advanced technology nodes such as 5 nm and 3 nm, the interconnect layer parasitic values for the wire segment could have 80%˜200% difference if the spacing distance to the neighbor is on the first pitch or on the second/third pitch.

Therefore, improving GR-vs-DR RC correlation to predict the track usage in GR to align with DR is important and challenging in global routing based design optimization flow. Detailed routing (DR) is performed based on the global routing (GR), after the nets are assigned to track and are DRC clean. However, the same net in global routing and detail routing may have differences/variations on (1) via overhang length, (2) net detour length, (3) routing layer usage, (4) the number of vias, and other parameters. In example designs, the differences between estimated wire lengths based on global routing and detailed routing was determined to be as high as 58%. Similarly, the differences between estimated number of vias based on global routing and detailed routing was determined to be as high as 30%.

Routing topology differences between global routing and detail routing can cause large parasitic resistance and capacitance miscorrelation between global routing optimization and detail routing optimization in a silicon compiler flow that performs placement and routing of the circuit design. The layer/via unit resistance can have significant impact in the circuit design. FIG. 2 shows unit resistance on routing layers from M0 to M14. M0 is 600 ohm/um, M14 is 0.083 ohm/um. FIG. 2 shows that the layer and via usage difference between global routing and detail routing can cause miscorrelated parasitics between these designs.

The system according to various embodiments precisely predicts circuit design parameters in global routing stage that align with the detail routing. This allows the system to get the more correlated parasitics and timing delay to achieve better quality of results in silicon compiler.

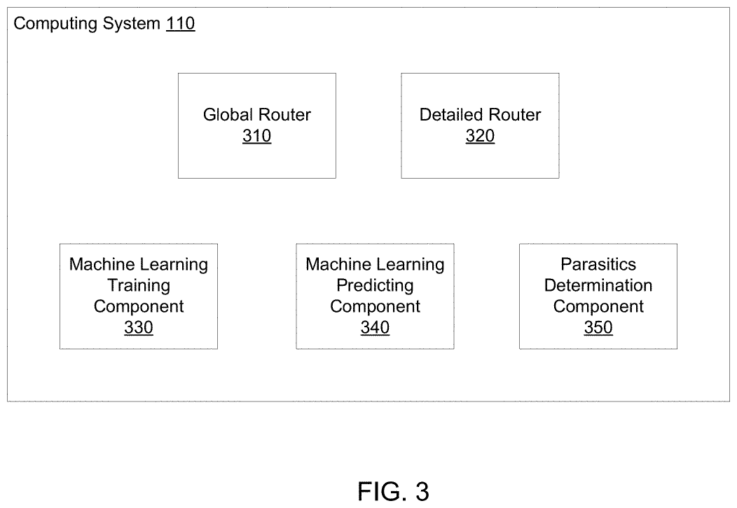

FIG. 3 shows a system architecture of a computing system for machine learning based predicting of detailed routing topology according to an embodiment. The computing system includes a global router 310, a detailed router 320, a machine learning training component 330, a machine learning predicting component 340, and a parasitics determination component 350. Other embodiments may include more or fewer components than indicated in FIG. 3.

The global router 310 performs global routing of the netlist. Global routing finds approximate routes between blocks of the circuit design. For example, global routing may first partition the routing region into blocks and determine block-to-block paths for all nets. Detailed routing takes the output from the global router and produces the exact geometric layout of the wires to connect the blocks. Accordingly, detailed routing determines the exact tracks and vias for nets. The detailed router 320 performs detailed routing of the netlist. Global routing design does not generate spacing distance information among the nets (track usage) for a net. Global routing is followed by detailed routing, which completes point-to-point connections between pins within each cell and specifies geometric information of the wires such as wire width and layer assignments. Detail routing assigns nets to tracks that conform to design rule checks (DRC).

The machine learning training component 330 trains one or more machine learning models for predicting detailed routing information. According to an embodiment, a machine learning model is trained to predict an attribute representing a track distance for a segment of a net of the netlist wherein the track distance represents a distance of the net from a neighboring net.

According to an embodiment, a machine learning model is trained to predict an attribute representing a difference between maximum layer determined by global routing and maximum layer determined by detailed routing. According to an embodiment, a machine learning model is trained to predict an attribute representing a difference between via number determined by global routing and via number determined by detailed routing. According to an embodiment, a machine learning model is trained to predict an attribute representing a difference between net length determined by global routing and net length determined by detailed routing. According to an embodiment, a machine learning model is trained to predict an attribute representing a difference between layer usage determined by global routing and layer usage determined by detailed routing.

The machine learning predicting component 340 predicts detailed routing information by executing the machine learning models trained by the machine learning training component 330. According to an embodiment, the predicted information is the spacing between segments. According to other embodiments, machine learning models may predict other detailed routing information as described herein.

The parasitics determination component 350 determines the parasitics of the netlist, for example, resistance and capacitance values of various segment based on the detailed routing information as predicted by the machine learning predicting component 340. According to an embodiment, the parasitics determination component 350 determines a parasitic resistance value by aggregating partial parasitic resistance values across a plurality of nets. Each of the partial parasitic resistance values may be predicted using a machine learning based model. According to an embodiment, the parasitics determination component 350 determines a parasitic capacitance value by aggregating partial parasitic capacitance values across a plurality of nets. Each of the partial parasitic capacitance values may be predicted using a machine learning based model. Since no tracks are assigned in the global routing, and routing topology is different in global routing design from detail routing design. The use of machine learning based models for predicting detailed routing information based on global routing information before actually performing the detailed routing ensures that the parasitics extracted in global routing design are correlated well with the parasitics extracted from detail routing design after the step 460.

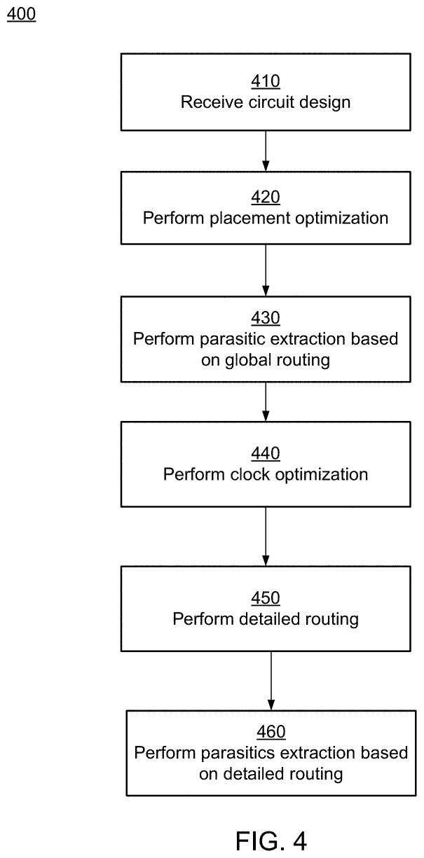

FIG. 4 illustrates an example process 400 for performing place and route of an electronic circuit design according to an embodiment. According to an embodiment, the system performing the process is a computing system, for example, the computing system 110 that includes various components of an IC compiler. The system receives 410 a circuit design, for example, a netlist representation of a physical design of a circuit. The system performs 420 placement optimization of the electronic circuit design. The system performs 430 parasitics extraction based on the global routing information. According to various embodiments, the system uses the machine learning models disclosed herein to determine accurate parasitics information based on the global routing information. The system further performs 440 clock optimization including clock synchronized tree optimization. The system performs 450 detailed routing based on the global routing results. The system performs 460 accurate parasitics extraction based on the detailed routing.

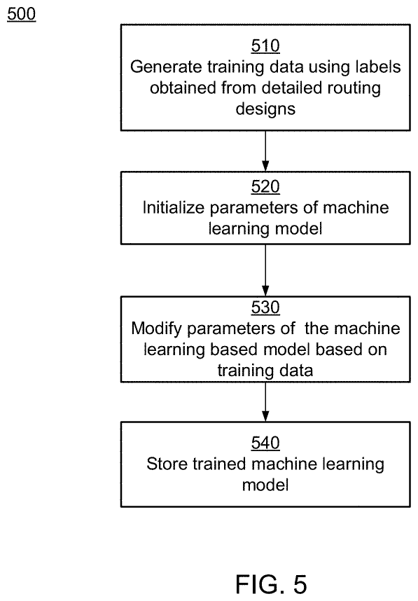

FIG. 5 is a flowchart illustrating a process 500 for training machine learning models for predicting detailed routing information based on global routing data, according to an embodiment. The system generates 510 training data using labels obtained from detailed routing designs. For example, the system collects labels/features from segments of nets in the detail routing designs.

According to various embodiments, the detailed label set from the segment of nets in detail routing design includes following feature names/identifiers and their corresponding description: (1) ntype: net type for clock net or signal net; (2) llayer: routing layer ID; (3) length: net length; (4) edgeLength: segment length; (5) fanout: number of fanout; (6) density: the nominal density of this edge; (7) mspace: routing layer min spacing; (8) mwidth: routing layer min width; (9) ndrspace: the non-default-rule spacing defined for this net; (10) ndrwidth: the non-default-rule width defined for this net; (11) ndrweight: the weight of non-default-rule; (12) ndrIgnorePG: non-default-rule ignore to PG (power and ground network); (13) threshold: non-default-rule threshold; and so on. A non-default rule is a routing rule that is not the default.

The system initializes 520 the parameters of a machine learning model, for example, a supervised machine learning model gradient boost regressor model for the track usage prediction. The model is configured to receive various features for a segment and predicts the spacing between the segment and another neighboring segment. According to an embodiment, the machine learning model predicts a track distance representing the distance between a segment and a nearby segment on the same layer. These segments could be from the different net or the same net.

The system modifies 530 the parameters of the machine learning model based on the training data, for example, by using gradient descent to minimize a loss value representing a difference between a predicted value and a label. The system stores 540 the parameters of the trained machine learning model.

According to an embodiment, the system uses a supervised machine learning model gradient boost regressor model that has faster training speed and higher efficiency, lower memory usage, better accuracy and is suitable for training with the large-scale data including millions of samples from detail routing designs.

According to an embodiment, a machine learning model (e.g., M_{TrackDistance}) is used to determine the predicted track distance (TrackDistance) using various input attributes such as netType, layerld, netLength, edgeLength, fanout, density, layerMinSpacing, layerMinWidth, ndr as shown in the following equation (1).

TrackDistance=M_{TrackDistance}(netType, layerld, netLength, edgeLength, fanout, density, layerMinSpacing, layerMinWidth, ndr . . . ) (1)

The system uses the predicted track distance (TrackDistance) to generate parasitics (resistance/capacitance RC). As shown in following equation (2), a model F is used to determine parasitics for an edge segment of the netlist using the attributes of the layer of the segment, the TrackDistance for the edge segment, the track density in the neighborhood of the edge segment and width of the edge segment. The RC parasitics determined for each edge segment are aggregated across all edge segments of the circuit design or a portion of the circuit design. In the equation (2), F represents a function for calculating RC values.

RC=Σᵢ₌₁ⁿ(layer, PredictedTrackDistance, density, width) (2)
n: num of edge segments of a globally routed net

From the sets of 5 nm and 3 nm detail routing designs and global routing designs, the system collects the following labels to obtain topology difference of the nets between detail routing design and global routing design. The extracted labels are used to train the machine learning based model (e.g., the lightGBM regressor model).

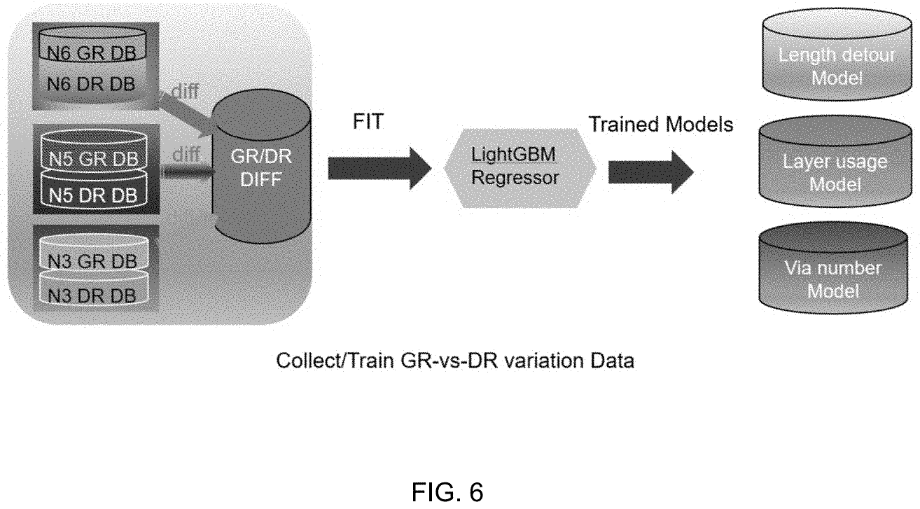

FIG. 6 illustrates process for generating training data based on variation between global routing and detailed routing according to an embodiment. The collected labels/features from global routing design and detail routing design: (1) netType: net type, clock or signal net; (2) driveLayer: drive pin layer; (3) loadLayer: load pin layer; (4) driveCoord: drive pin coordinates x and y; (5) loadCoord: load pin coordinates x and y; (6) netLength: net length (7) fanout: fanout number (8) layer: the maximum layer of the net; (9) numVia: the number of via; (10) layerNUsage (for layer N): layer usage from layer 0 to layer 19; (11) layerNDensity for layer N: layer density from layer 0 to layer 19; (12) layerMinSpacing: layer min space from layer 0 to layer 19; (13) layerMinWidth: layer min width from layer 0 to layer 19. According to various embodiments, different ML models are trained to predict different detailed routing related attributes, for example, a model M_{layerDiff} is trained to predict a value layerDiff representing a difference between maximum layer determined by global routing and maximum layer determined by detailed routing; a model M_{viaDiff} is trained to predict value viaDiff representing a difference between via number determined by global routing and via number determined by detailed routing; a model M_{lengthDiff} is trained to predict lengthDiff representing a difference between net length determined by global routing and net length determined by detailed routing; a model M_{layerUsageDifference} is trained to predict a value layerUsageDifference representing a difference between layer usage determined by global routing and layer usage determined by detailed routing; and so on.

The saved pre-trained models are loaded into a global routing extractor to get the prediction values for via overhang difference, via number difference, net length difference, layer usage difference, and so on and use them to modify the net topology used for RC extraction in global routing design. The following equations are used to determine partial parasitics contributions by each attribute viaDiff, layerDiff, and lengthDiff.

According to an embodiment, a regressor model predicts viaDiff. The machine learning model M_{viaDiff} receives as input, features including fanout, numVia, maxLayer, layer1Usage . . . layerNUsage, layer1Density, layerNDensity, netType, driveLayer, loadLayer, driveCoord, loadCoord, netLength, layer1Spacing, . . . layerNSpacing and predicts the value of the viaDiff. ViaRes(v) represents the resistance from a via device. The partial parasitics contribution by feature viaDiff is determined as a weighted aggregate of the values of viaDlff determined for each stack via ID as shown by equation (3).

$$RC 1 ( viaDiff ) = {\sum }_{v = 1}^{N} ViaRes ( v ) * {M}_{viaDiff} ( fanout , numVia , maxLayer , layer 1 Usage layerNUsage , layer 1 Density , layerNDensity , netType , driveLayer , loadLayer , driveCoord , loadCoord , netLengthy , layer 1 Spacing , … layerNSpacing … ) ; \qquad ( 3 )$$

v is stack via ID from 1 to N.

The machine learning model (a regressor model) that predicts layerDiff is referred to as M_{layerDiff}. The machine learning model rM_{layerDiff} receives as input various features including fanout, numVia, maxLayer, layer1Usage . . . layerNUsage, layer1Density, layerNDensity, netType, driveLayer, loadLayer, driveCoord, loadCoord, netLength, layer1Spacing, . . . layerNSpacing and predicts the value of the layerDiff. In following equation (4) layerRC(1) represents the parasitics (resistance and capacitance) from the specific routing layer (1). The RC (resistance and capacitance) are calculated from the layer segments on the routing layers. The partial parasitics contribution by feature layerDiff is determined as a weighted aggregate of the values of layerDiff determined for each stack layer ID as shown by equation (4).

$$RC 2 ( layerDiff ) = {\sum }_{l = 1}^{N} layerRC ( l ) * {M}_{layerDiff} ( fanout , numVia , maxLayer , layer 1 Usage … layerNUsage , layer 1 Density , layerNDensity , netType , driveLayer , loadLayer , driveCoord , loadCoord , netLengthy , layer 1 Spacing , … layerNSpacing ) \qquad ( 4 )$$

wherein, l is stack layer ID from 1 to N.

The machine learning model that predicts lengthDiff is referred to as M_{lengthDiff}. The machine learning model M_{lengthDiff} receives as input various features including fanout, numVia, maxLayer, layer1Usage . . . layerNUsage, layer1Density, layerNDensity, netType, driveLayer, loadLayer, driveCoord, loadCoord, netLength, layer1Spacing, layerNSpacing and predicts the value of the lengthDiff. In equation (5), layerRC(1) represents the parasitics (resistance and capacitance) from the specific routing layer (1). The RC (resistance and capacitance) are calculated from the layer segments on the routing layers. The partial parasitics contribution by feature lengthDiff is determined as a weighted aggregate of the values of lengthDiff determined for each stack layer ID as shown by equation (5).

$$RC 3 ( lengthDiff ) = {\sum }_{l = 1}^{N} layerRC ( l ) * {M}_{lengthDiff} ( fanout , numVia , maxLayer , layer 1 Usage , … layerNUsage , layer 1 Density , … layerNDensity , netType , driveLayer , loadLayer , driveCoord , loadCoord , netLengthy , layer 1 Spacing , … layerNSpacing ) \qquad ( 5 )$$

wherein, l is stack layer ID from 1 to N

The system determines a partial parasitics contribution based on features layer, density, spacing, and width using equation 1. The partial parasitics contributions corresponding to various features viaDiff, layerDiff, lengthDiff, and the features layer, density, spacing, width are combined and aggregated across i=1 . . . n, i.e., across all routing layers used in this net using equation (6).

$$RC = {\sum }_{i = 1}^{N} ( RC ( layer , density , spacing , width ) + RC ( viaDiff ) + RC 2 ( layerDiff ) + RC 3 ( lengthDiff ) ) \qquad ( 6 )$$

The machine learning models are trained and saved. The system extracts capacitance and resistance and determines these RC correlation results with the detailed routing RC results. Experimental results show that a global routing extractor using machine learning based model according to various embodiments has better correlation with results of detailed router compared to a conventional global routing extractor (that is not based on the machine learning based techniques disclosed herein). The improvement in correlation is from 2% to 14%.

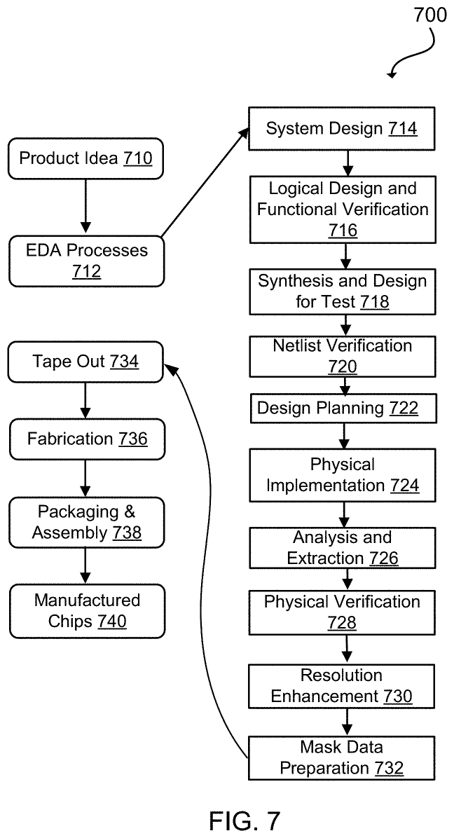

FIG. 7 illustrates an example set of processes 700 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 710 with information supplied by a designer, information which is transformed to create an article of manufacture that uses a set of EDA processes 712. When the design is finalized, the design is taped-out 734, which is when artwork (e.g., geometric patterns) for the integrated circuit is sent to a fabrication facility to manufacture the mask set, which is then used to manufacture the integrated circuit. After tape-out, a semiconductor die is fabricated 736 and packaging and assembly processes 738 are performed to produce the finished integrated circuit 740.

Specifications for a circuit or electronic structure may range from low-level transistor material layouts to high-level description languages. A high-level of abstraction may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower abstraction level that is a less abstract description adds more useful detail into the design description, for example, more details for the modules that include the description. The lower levels of abstraction that are less abstract descriptions can be generated by a computer, derived from a design library, or created by another design automation process. An example of a specification language at a lower level of abstraction language for specifying more detailed descriptions is SPICE, which is used for detailed descriptions of circuits with many analog components. Descriptions at each level of abstraction are enabled for use by the corresponding tools of that layer (e.g., a formal verification tool). A design process may use a sequence depicted in FIG. 7. The processes described by be enabled by EDA products (or tools).

During system design 714, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 716, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 718, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 720, the netlist is checked for compliance with timing constraints and for correspondence with the HDL code. During design planning 722, an overall floor plan for the integrated circuit is constructed and analyzed for timing and top-level routing.

During layout or physical implementation 724, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 726, the circuit function is verified at the layout level, which permits refinement of the layout design. During physical verification 728, the layout design is checked to ensure that manufacturing constraints are correct, such as DRC constraints, electrical constraints, lithographic constraints, and that circuitry function matches the HDL design specification. During resolution enhancement 730, the geometry of the layout is transformed to improve how the circuit design is manufactured.

During tape-out, data is created to be used (after lithographic enhancements are applied if appropriate) for production of lithography masks. During mask data preparation 732, the ‘tape-out’ data is used to produce lithography masks that are used to produce finished integrated circuits.

A storage subsystem of a computer system may be used to store the programs and data structures that are used by some or all of the EDA products described herein, and products used for development of cells for the library and for physical and logical design that use the library.

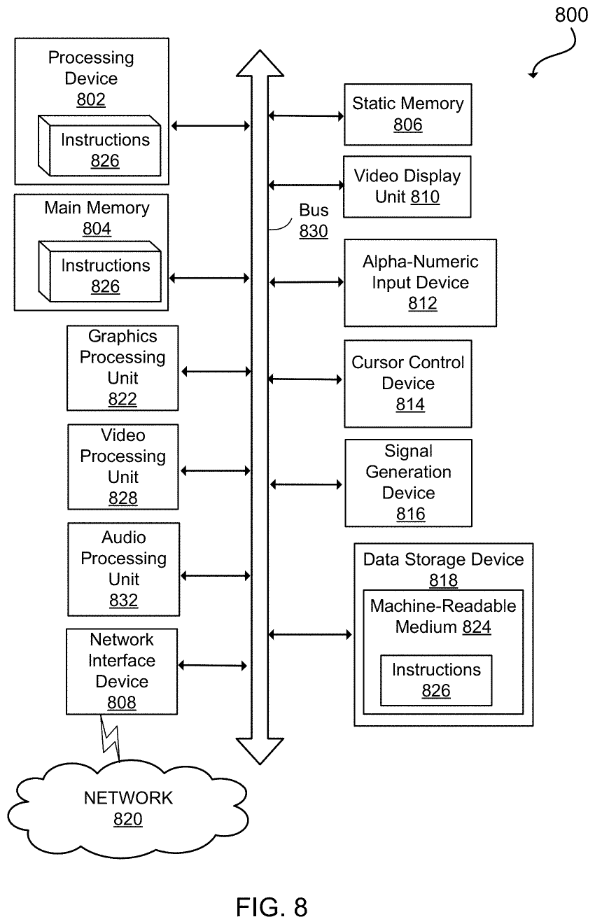

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
receiving a netlist representation of a circuit design;
performing, by a processor, global routing using the netlist representation to generate a set of segments, wherein a segment represents a portion of a net routed by the global routing;
providing features extracted from a segment as input to one or more machine learning models, each of the one or more machine learning models configured to predict attributes of the input segment;
executing the one or more machine learning models to predict attributes of each of a set of segments output by global routing of the netlist; and
determining parasitic resistance and parasitic capacitance values for nets of the circuit design based on the predicted attributes.

2. The method of claim 1, wherein a machine learning model of the one or more machine learning models is trained to predict an attribute representing a track distance for a segment of a net of the netlist, the track distance representing a distance from a neighboring net, wherein executing the one or more machine learning models comprises:
executing the machine learning model to predict track distance for a particular segment of a net of the netlist, the track distance representing a distance from a neighboring net.

3. The method of claim 1, wherein a machine learning model of the one or more machine learning models is trained to predict an attribute representing a difference between maximum layer determined by global routing and maximum layer determined by detailed routing.

4. The method of claim 1, wherein a machine learning model of the one or more machine learning models is trained to predict an attribute representing a difference between via number determined by global routing and via number determined by detailed routing.

5. The method of claim 1, wherein a machine learning model of the one or more machine learning models is trained to predict an attribute representing a difference between net length determined by global routing and net length determined by detailed routing.

6. The method of claim 1, wherein a machine learning model of the one or more machine learning models is trained to predict an attribute representing a difference between layer usage determined by global routing and layer usage determined by detailed routing.

7. The method of claim 1, wherein determining parasitic resistance values for a net comprises aggregating partial parasitic resistance values across a plurality of nets, wherein the partial parasitic resistance values are predicted using one or more machine learning based models.

8. The method of claim 1, wherein determining parasitic capacitance values for a net comprises aggregating partial parasitic capacitance values across a plurality of nets, wherein the partial parasitic capacitance values are predicted using one or more machine learning based models.

9. The method of claim 1, wherein determining parasitic resistance and capacitance values for a net comprises aggregating partial parasitic resistance and capacitance values across a plurality of nets, wherein the partial parasitic resistance and capacitance values are predicted using:
a first machine learning model trained to predict an attribute representing a track distance for a segment of a net of the netlist, the track distance representing a distance from a neighboring net;
a second machine learning model trained to predict an attribute representing a difference between via number determined by global routing and via number determined by detailed routing;
a third machine learning model trained to predict an attribute representing a difference between layer usage determined by global routing and layer usage determined by detailed routing; and
a fourth machine learning model trained to predict an attribute representing a difference between net length determined by global routing and net length determined by detailed routing.

10. The method of claim 1, wherein the features extracted from a segment of a net that are provided as input to a machine learning model comprise one or more of:
net type;
net length;
segment length;
routing layer minimum spacing; and
routing layer minimum width.

11. A non-transitory computer readable storage medium comprising stored instructions, which when executed by one or more computer processors, cause the one or more computer processors to:
receive a netlist representation of a circuit design;
perform global routing using the netlist representation to generate a set of segments, wherein a segment represents a portion of a net routed by the global routing;
provide features extracted from a segment as input to one or more machine learning models, each of the one or more machine learning models configured to predict attributes of the input segment;
execute the one or more machine learning models to predict attributes of each of a set of segments output by global routing of the netlist; and
determine parasitic resistance and parasitic capacitance values for nets of the circuit design based on the predicted attributes.

12. The non-transitory computer readable storage medium of claim 11, wherein a machine learning model is trained to predict an attribute representing a track distance for a segment of a net of the netlist, the track distance representing a distance from a neighboring net, wherein instructions for executing the one or more machine learning models cause the one or more computer processors to:
execute the machine learning model to predict track distance for a particular segment of a net of the netlist, the track distance representing a distance from a neighboring net.

13. The non-transitory computer readable storage medium of claim 11, wherein a machine learning model is trained to predict an attribute representing a difference between maximum layer determined by global routing and maximum layer determined by detailed routing.

14. The non-transitory computer readable storage medium of claim 11, wherein a machine learning model is trained to predict an attribute representing a difference between via number determined by global routing and via number determined by detailed routing.

15. The non-transitory computer readable storage medium of claim 11, wherein a machine learning model is trained to predict an attribute representing a difference between net length determined by global routing and net length determined by detailed routing.

16. The non-transitory computer readable storage medium of claim 11, wherein a machine learning model is trained to predict an attribute representing a difference between layer usage determined by global routing and layer usage determined by detailed routing.

17. The non-transitory computer readable storage medium of claim 11, wherein instructions to determine parasitic resistance and parasitic capacitance values for a net comprise instructions to aggregate partial parasitic resistance and partial parasitic capacitance values across a plurality of nets, wherein the partial parasitic resistance and capacitance values are predicted using one or more machine learning based models.

18. The non-transitory computer readable storage medium of claim 11, wherein instructions to determine parasitic resistance and capacitance values for a net comprise instructions to aggregate partial parasitic resistance and capacitance values across a plurality of nets, wherein the partial parasitic resistance and capacitance values are predicted using:
a first machine learning model trained to predict an attribute representing a track distance for a segment of a net of the netlist, the track distance representing a distance from a neighboring net;
a second machine learning model trained to predict an attribute representing a difference between via number determined by global routing and via number determined by detailed routing;
a third machine learning model trained to predict an attribute representing a difference between layer usage determined by global routing and layer usage determined by detailed routing; and
a fourth machine learning model trained to predict an attribute representing a difference between net length determined by global routing and net length determined by detailed routing.

19. The non-transitory computer readable storage medium of claim 11, wherein the features extracted from a segment of a net that are provided as input to a machine learning model comprise one or more of:
net type;
net length;
segment length;
routing layer min spacing; and
routing layer min width.

20. A system comprising:
one or more computer processors; and
a non-transitory computer readable storage medium comprising stored instructions, which when executed by one or more computer processors, cause the one or more computer processors to:
receive a netlist representation of a circuit design;
perform global routing using the netlist representation to generate a set of segments, wherein a segment represents a portion of a net routed by the global routing;
provide features extracted from a segment as input to one or more machine learning models, each of the one or more machine learning models configured to predict attributes of the input segment;
execute the one or more machine learning models to predict attributes of each of a set of segments output by global routing of the netlist; and
determine parasitic resistance and parasitic capacitance values for nets of the circuit design based on the predicted attributes.
